(19) United States
(12) Patent Application Publication
(10) Pub. No.: US 2010/0025095 A1
(43) Pub. Date: Feb. 4, 2010

(54) Device Carrying an Intergrated Circuit/Components and Method of Producing the Same

(76) Inventors: Li Hui Guo, Singapore (SG); Qing Xin Zhang, Singapore (SG)

Correspondence Address: CONNOLLY BOVE LODGE & HUTZ LLP, 1875 EYE STREET, N.W., SUITE 1100, WASHINGTON, DC, 20006, US

(21) Appl. No.: 12/083,442

(22) PCT Filed: Oct. 12, 2005
(86) PCT No.: PCT/SG2005/000352

§ 371 Date: Apr. 20, 2009

(51) Int. Cl. H05K 1/16; H05K 3/30

(52) U.S. Cl. 174/260; 29/832

(57) ABSTRACT

A method of forming an integrated circuit component on an insulating substrate (21), comprising providing a first layer arrangement and a second layer arrangement, each layer arrangement comprising a supply substrate and a dielectric layer (17), the dielectric layer of at least one of the layer arrangements comprising the integrated circuit component therein; attaching the first layer arrangement on one surface of the insulating substrate with the dielectric layer of the first layer arrangement facing the insulating substrate, and attaching the second layer arrangement on an opposing surface of the insulating substrate with the dielectric layer of the second layer arrangement facing the insulating substrate, wherein the first layer arrangement and the second layer arrangement are so arranged to sandwich at least a portion of the insulating substrate between the first and second layer arrangements.

The invention relates to multi-layer integrated circuit components, in particular, multi-layer integrated passive components that are integrated on insulating substrates. This invention also relates to a method for producing multi-layer circuit components on insulating substrates.

### BACKGROUND OF THE INVENTION

Over the last decade, the miniaturisation of circuit components has taken on an integral role in the development of electronics communication modules. Miniaturisation has been driven largely by portability requirements of mobile telecommunications devices. Most of the devices in cell phones are passive components such as capacitors and resistors. For example, a typical cell phone typically contains 400 components, where tens of the components are either active devices or integrated circuits (IC), while the remaining hundreds of the components are passive components such as resistors or capacitors. For this reason, passive components largely determine the area of the circuit board, and thus also the size of the cell phones.

Although current technology enables relatively small discrete passive components to be fabricated, there are limits to the extent by which miniaturization of such components are capable of fulfilling consumer portability requirements, particularly when a large number of passive components are to be integrated on the surface of a circuit board and used for small devices, e.g., in a cell phone or mp3 player circuit board.

In order to further decrease the size of integrated circuits, the integration of passive components beneath the surface of the circuit board has been implemented. The article “Putting Passives in Their Place” by Ulrich et al. (“Putting Passives in Their Place”, IEEE Spectrum, July 2003, pp. 26-30.) describes the drastic reduction of the size of an ordinary circuit board by removing passive components that are conventionally soldered onto the surface of a circuit board, and placing them, instead, onto a semiconductor substrate located within the circuit board. In such an arrangement, resistors comprise copper connection points bridged by resistive film, while capacitors comprise conductive paste separated by a thin film of dielectric material.

While the fabrication of passive components on semiconductor substrates can achieve high component density and also benefit from the low cost of standard semiconductor technology, it has been found that quality of cross-talk through the semiconductor substrate becomes significantly diminished. One factor which has been identified as a cause of poor cross-talk quality is low resistivity of the semiconductor substrates (most commonly silicon wafers). Quality of cross-talk communication is an important consideration in circuit miniaturization, and is crucial in applications such as wireless communications. For example, radio frequency (RF) integrated circuits and high-speed digital integrated circuits require both high RF performance and high density of passive components in order to meet the challenges of high functional systems with small volume size.

Recently, it has been found that passive components that are fabricated on insulating substrates have improved RF performance and crosstalk suppression. Current efforts are thus directed towards the integration of passive components on insulating substrates instead of semiconductor substrates.

U.S. Pat. No. 6,021,050 discloses a method for producing multi-layer printed circuit board (PCB) having integrated passive components fabricated on one or more intermediate layers of the PCB. Passive components are fabricated from polymer film inks which are screen printed onto thin PCBs, and then fired at temperatures compatible with common insulating PCB materials, such as glass or epoxy (FR4, FR5, etc.). Finally individual PCBs are bonded together to form multi-layer PCB. However, the use of film ink printing and PCB process leads to much larger PCB dimensions and value tolerance of passive components. In addition, the fabrication temperature is ideally under 250° C. for PCB process. This lower limit may cap the potential application of new functional material, e.g. high-k material, and consequently limit the integration of functional components beyond conventional resistors, capacitors and inductors, such as high-density capacitors and low loss RF filters.

European Patent No. 0813355 discloses an alternative process in which a capacitor is produced in an electronic circuit package by coating a dielectric layer on a first conductor foil and layering a second conductor foil on top of the dielectric layer. The foils with capacitors are further laminated with insulating PCB to form embedded capacitors in the PCB.

In another document, Tumala et al. (“Gigabit Wireless: System-on-a-Package Technology”, Proceedings of the IEEE, vol. 92, No. 2, 2004, pp. 376-387.) describes another approach for fabricating integrated passive component systems, known as the system-on-a-package (SOP) approach. The document describes principles involved in implementing SOP with reference to designing wireless communication systems, including systems which comprise integrated passive components, such as multi-layered filters, integrated antennas and multi-layered baluns.

In order to avoid poor cross-talk quality that is partly caused by direct fabrication of passive components on insulating substrates, several techniques in current semiconductor technology have been employed to transfer integrated passive circuits onto an insulating substrate. In particular, small dimension and high-density passive components are pre-fabricated on semiconductor substrates, preferably silicon wafers, and transferred to another substrate with good resistivity property. One such technique is known as wafer transfer technology (WTT), which is able to integrate passive components in high density, high quality and low cost.

R. Dekker et al. (“Substrate Transfer for RF Technologies”, IEEE Trans. on Electron Devices, Vol. 50, No. 3, pp. 747-757, 2003) describes a method of transferring integrated circuits fabricated on silicon substrates to alternate substrates, preferably glass substrates. Primer and UV sensitive glue are spun on the silicon wafer, which is then attached to a glass substrate. Under UV exposure through the glass, the glue is cured, and thereby bonding the silicon wafer with the glass substrate. In case of an opaque substrate other than glass, UV lighting process is not suitable because UV light cannot penetrate the opaque substrate to activate the glue. Dekker proposes to apply a thermal process for bonding the silicon wafer with the opaque substrate. However, due to differences in thermal expansion coefficients between the two substrates, the thermal process may introduce stress and eventually warp the substrate when it is cooled to room temperature.

In another document, Sundaram et al. (2001 Electronic Components and Technology Conference page 535-540) discloses a process for fabricating integrated circuits comprising providing a core epoxy substrate with copper foil on both sides, vacuum laminating a thick dry film photoresist on the copper foil on both sides, etching patterned portions of the photoresist to form circuitry interconnections, and building-up alternating layers of copper and dielectric layers. The metal lines and components are directly fabricated on the insulating substrate, one layer by one layer, on the both sides of it for surface flat.

European Patent No. 0152634 refers to a method of manufacturing a printed wiring board incorporating an insulating layer and a conductor circuit layer, by enabling the conductor circuit layer and a plating resist to adhere to a metallic board in the course of plating and enabling them to peel thoroughly from the metallic board.

U.S. Pat. No. 5,647,966 discloses a method for producing a conductive pattern. On a conductive base plate, a mask layer with a pattern defining an exposed area of the conductive base plate is firstly formed, and a conductive pattern is accordingly formed on the exposed area of the conductive base plate by electroforming. The conductive pattern is finally transferred to a support layer.

Despite the developments that have taken place, limitations in current techniques of integrating circuit (IC) components in insulating substrates still exist for which continuing efforts are needed to improve their performance.

Accordingly, it is an object of the present invention to provide a method of fabricating an IC component onto an insulating substrate, which allows any IC components fabricated on semiconductor substrates to be transferred to any insulating substrate. It is also an object of this invention to obtain integrated components on insulating substrates with good flatness using stress compensation, which is suitable for post-processing.

### SUMMARY OF THE INVENTION

According to a first aspect of the present invention, there is provided a method of forming an integrated circuit component on an insulating substrate. The method comprises providing a first and a second layer arrangement, wherein each layer arrangement comprises a supply substrate and a dielectric layer. The dielectric layer of at least one of the first and the second layer arrangements further comprises the integrated circuit component therein. The first layer arrangement is attached to one surface of the insulating substrate with the dielectric layer of the first layer arrangement facing the insulating substrate. The second layer arrangement is attached to an opposing surface of the insulating substrate with the dielectric layer of the second layer arrangement facing the insulating substrate. The first layer arrangement and the second layer arrangement are so arranged to sandwich at least a portion of the insulating substrate between the first and the second supply substrates.

In another aspect, the invention relates to a device carrying an integrated circuit component. The device comprises a first dielectric layer, a second dielectric layer and an insulating substrate, wherein the first dielectric layer and the second dielectric layer are attached to two opposing surfaces of the insulating substrate, respectively. The first and the second dielectric layers are so arranged such that at least a portion of the insulating substrate is sandwiched between the first and the second dielectric layers. At least one of the first and the second dielectric layers comprises an integrated circuit component therein.

These aspects of the invention will be more fully understood in view of the following description, drawings and non-limiting examples.

### BRIEF DESCRIPTION OF THE DRAWINGS

FIGS. 1A and 1B shows an example of a layer arrangement wherein integrated components are fabricated on a semiconductor substrate.

FIGS. 2A, 2B and 2C shows the process of integrating electronic components on an insulating substrate according to the first embodiment of this invention.

FIGS. 3A and 3B shows another embodiment of this invention wherein pre-grinding is performed.

FIG. 4 shows a post-processing to the device which contains integrated components on an insulating substrate.

FIGS. 5 to 8 are graphs comparing data measurements showing the performance of a device that is fabricated by wafer transfer technology (WTT) onto an insulating substrate according to the method of the present invention, as compared to a device that is fabricated onto silicon according to conventional methods.

FIG. 5 is a graph of Q-value and Inductance (nH) vs Frequency (GHz), tested from integrated inductors on organic substrate and on Si substrate respectively. The graph shows that high Q-value is achieved for the integrated inductor on organic substrate.

FIG. 6 is a graph of maximum Q-value and Resonant Frequency vs. Frequency for a set of integrated inductors.

FIG. 7 is a graph of Loss (dB/mm) vs Frequency (GHz) tested from a Coplanar-Waveguide (CPW) fabricated, separately, on insulators, RO3004, FR-4 and Glass, and compared with a Coplanar-Waveguide (CPW) fabricated on silicon. The graph shows a CPW with very low loss on insulators fabricated by this invention.

FIG. 8 is a graph of S21 Magnitude (dB) vs. Frequency (GHz) for indicating signal cross-talk between two metal pads to verify the signal cross-talk. The metal pads were fabricated on organic substrate FR-4 and Si. As a reference, the data in the air is also indicated. The graph shows that strong cross-talk suppression is achieved by fabricating components on an insulator using the method of this invention.

FIG. 9A shows the layout of a test device comprising a transistor with 4 attached pads, which is analysed for its performance. A first device is fabricated by WTT onto an insulating substrate according to the method of the present invention, and an identical second device that is fabricated onto silicon according to conventional methods. FIG. 9B compares the performance of a n-type MOS device having gate width to gate length ratio of 20 um to 600 nm, while FIG. 9C shows the performance of a n-type MOS device having gate width to gate length ratio of 2 um to 160 nm.

FIG. 10 is a graph of Capacitance (pF) vs. Area (×10³ um²) of a capacitor.

FIG. 11 is Current (mA) vs. Voltage Drop (V) of two resistors, comparing the resistance of a resistor on Si and a resistor on insulator fabricated by WTT of this invention. The variation caused by this invention is very limited.

FIGS. 12A and 12B show the graphs of Probability vs. Resistance (Ohm) of via-chains on Si and on insulator fabricated according to the method of the invention. These graphs show that the variation caused by this invention is very limited.

### DETAILED DESCRIPTION

The present invention is based on the finding that the warping of integrated circuit boards, typically caused by thermally-induced expansion and/or contraction during fabrication resulting in stresses being generated at the interface between the insulating substrate and integrated circuit layer arrangement, can be reduced or even eliminated by balancing this interfacial stress on the opposing side of the insulating substrate. By providing a method for fabricating an integrated circuit board in which a second layer arrangement is fabricated onto an opposite surface of the circuit board so that interfacial stress created on one surface of the insulating substrate is counteracted by interfacial stress created on the opposite surface of the insulating substrate. By minimising thermally-induced warping of the integrated circuit boards, this method also allows passive components/circuits that are pre-fabricated onto silicon wafers to be transferred onto insulating substrates (both opaque and transparent) using conventional printed circuit board lamination machines and adhesive films.

The invention has several advantages compared to existing technologies for integrating passive components on insulating substrates. Firstly, the attachment of pre-fabricated circuit layers onto a substrate allows passive components/circuits with small dimensions and small tolerances to be integrated into the circuit, thereby enabling very accurate patterns can be produced on silicon prior to attachment to the insulating substrate. Furthermore, compared to existing technology of embedding passive components into plastics, the present method can withstand high process temperatures because the electrical components are fabricated on silicon wafers. Therefore, ferroelectric materials with ultra-high k (dielectric constant) of more than 3000 can be integrated so that very high capacitor densities can be obtained. Very thin dielectric layers used for Metal-Insulator-Metal (MIM) capacitors are also compatible with the method, thereby increasing the density of MIM capacitors on the dielectric layers. For passive circuits, each layer can be as thin as only a few micrometers. Therefore, it enables the package to weigh less than traditional packages using conventional embedding technology where each layer thickness is at least several tens of micrometers. Another advantage of this invention is that the fabrication process is carried out under standard semiconductor process conditions using standard printed circuit board (PCB) packaging lamination without requiring the installation of new facilities. For this reason, the invention can be easily integrated with existing manufacturing facilities.

In the present invention, two layer arrangements, of which at least one comprises an integrated circuit component, are provided for attachment onto an insulating substrate. Each layer arrangement comprises a supply substrate covered with a dielectric layer on one surface. One or both of the layer arrangements may comprise IC components. Each layer arrangement may be fabricated using any existing materials, processes and technologies for fabricating integrated circuits and passive components. If only one layer arrangement comprise IC components, the other layer arrangement that does not have any IC components present therein is provided for the purpose of surface stress compensation on the opposing surface of the insulating substrate. For this purpose, the layer arrangement having no IC components preferably comprises the same dielectric layer material and layer structure as the layer having IC components.

The supply substrate can be prepared from semiconductor materials as well as metal materials. Typical semiconductor materials include silicon, germanium, GaAs, InP, SiC, GaN, SiGe, etc. Silicon is widely used for integrated circuit substrates due to its low cost, reasonable speed, ease of processing and suitability for processing within a convenient temperature range. Thus, in a preferred embodiment, silicon is selected as the supply substrate. The supply substrate is present in the fabricated IC device only during fabrication, and is removed to expose the dielectric layer along with its IC components, if present, in the finished device. Because silicon is not the final carrier substrate, it is not necessary to use high quality silicon. Accordingly, low purity single crystalline silicon may be used in the present invention. In another embodiment, low purity poly-crystalline silicon is used.

The supply substrate can be cut according to predetermined dimensions required for its fitting into an intended device. One or more dielectric layers are then formed on the prepared supply substrate. At least one of the dielectric layers contains IC components and related circuitry. The IC components and related circuitry may be fabricated in dielectric layers using thin film technology, including chemical vapor decomposition (CVD), physical vapor decomposition (PVD), ion implantation, rapid thermal processing (RTP), vacuum annealing, electroplating, Ink-Jet printing, etc. If small dimension patterns are to be obtained, lithography technology may also be used. Alternatively, thick film technology may be used to fabricate integrated circuit embedded in dielectric layers. Some examples of thick film process include tape casting, screen printing and spraying methods. The sol-gel technology may also be used in the fabrication. Furthermore, special materials may be used to make special components. For example, high-k dielectric material or ferroelectric material can be used to produce high-density metal-insulator-metal capacitors under high temperature.

Other types of conventional IC components can be obtained from any suitable process, such as bipolar technology, CMOS technology, bipolar complementary metal oxide semiconductor (BiCMOS) technology and any new technology, wherein CMOS is most commonly used. An integrated circuit may consist of interconnected semiconductor devices, including active components and passive components, as well as I/O pads, metal wires, antennas and synthetic function blocks, etc. Examples of passive components include resistors, capacitors, inductors, high-density metal-insulator-metal capacitors and low loss RF filters. Examples of active components include transistors, amplifiers, transmitters and LEDs. In a preferred embodiment, only passive components are integrated into the layer arrangement. In another embodiment, the integrated circuits in the layer arrangement comprise both active components and passive components.

The attachment of the first layer arrangement and second layer arrangement onto the surface of the insulating substrate is carried out such that the dielectric layers of each layer arrangement are arranged to face the insulating substrate. The attachment of the dielectric layer onto the insulating substrate may be carried out under any suitable temperature and pressure required by the bonding process that is used for the attachment. Typically, the temperature under which attachment is carried out is in the range of about 100° C. to about 300° C., which is acceptable for a silicon supply substrate. In a preferred embodiment, normal PCB lamination process is used to carry out the attachment. Typical adhesives may be used for the purpose of attachment, such as epoxy glue. In other embodiments, common semiconductor bonding may be used, such as eutectic alloy bonding, polymer bonding, glass bonding and solder bonding.

When carrying out the steps of attaching the first and the second layer arrangements onto the insulating substrate, the first layer arrangement and the second layer arrangement are arranged so as to sandwich at least a portion of the insulating substrate between them, such that this sandwiched portion of the insulating substrate is located directly between the layer arrangements. In other words, the two layer arrangements are superimposed either partially or entirely on the two opposite surfaces of the insulating substrate, the superimposed portion being the portion of the insulating substrate which is sandwiched between the first and the second layer arrangements.

Depending on whether integrated components are present in the layer arrangements, the first and the second layer arrangements may be aligned to achieve stress balance on both sides of the insulating substrate. For example, the first layer arrangement may be at least substantially aligned with the second layer arrangement, so that the portions of the insulating substrate are sandwiched between the first and the second layer arrangements. In a preferred embodiment, the two layer arrangements are selected and arranged to be mutually matching on opposite sides of the insulating substrate, meaning that one layer arrangement entirely overlaps the other layer arrangement on the opposite side of the insulating substrate, i.e. the first layer arrangement and the second layer arrangement are so arranged to sandwich the insulating substrate entirely between the first layer arrangement and the second layer arrangement. In another embodiment, one layer arrangement only partially overlaps the other layer arrangement. Besides having the two layer arrangements, additional layer arrangements may also be respectively attached to the two opposing surfaces of the insulating substrate, therefore achieving stress balance between the two sides of the insulating substrate.

An alternative to the aligning requirement specified above is the selection of appropriate materials and dimensions for each layer arrangement, so that alignment of the layer arrangements is not necessary for achieving stress balance.

In a preferred embodiment, two layer arrangements are simultaneously attached to the insulating substrate at substantially the same ambient temperature. The material of insulating substrate may be transparent or opaque, selected from glass, ceramics, rubber, organic material (e.g. FR- and RO-series) or any other insulating materials or a combination thereof. The properties of the two layer arrangements are selected such that the interfacial stress between the first layer arrangement and the insulating substrate is compensated by the interfacial stress between the second layer arrangement and the insulating substrate. In this case, the multi-layer device including integrated circuit will not warp when the temperature falls from bonding temperature to room temperature. For example, each layer arrangement is fabricated using the same set of materials.

In a preferred embodiment, the thickness of the first and the second layer arrangement is selected to be at least substantially identical. More preferably, the thickness of particularly the supply substrate of the first layer arrangement and the supply substrate of the second layer arrangement are selected to be at least substantially identical. Alternatively, the dielectric layer of the second layer arrangement is selected to be at least substantially identical in structure to the dielectric layer of the first layer arrangement. This selection would allow stress compensation to be maintained even after the supply substrates are removed. Additionally, the number of layers may be chosen to be identical in both first and second layer arrangements. In a particularly preferred embodiment, the dielectric layers of the first and the second layer arrangements comprise or are selected to have the same or at least substantially similar layer structure and layer materials. In other words, the two opposing dielectric layers respectively contain the same or at least substantially similar number of discrete layers, wherein each discrete layer in the first dielectric layers consists of the same material and the same thickness with each corresponding discrete layer in the second dielectric layers.

In another preferred embodiment, the coefficient of thermal expansion (CTE) between the first layer arrangement and the insulating substrate is selected to be substantially identical to the CTE between the second layer arrangement and the insulating substrate. In a preferred embodiment, the CTE of the supply substrates from the first and the second layer arrangements is selected to be identical. This selection ensures that the layer arrangements on both surfaces of the insulating substrate contract to the same extent when cooled from high temperatures during fabrication. In order to carry out such a selection to achieve equality of CTE, two supply substrates comprising similar dimensions and materials and each having dielectric layers of the same dimensions and material may be used. This selection can be made regardless of whether one of the dielectric layers has embedded IC components. As the thickness of the supply substrate is much larger than that of the dielectric layers built onto it, the CTE of the overall layer arrangement is determined by the characteristics of the thicker layer, i.e. the supply substrate.

In one embodiment, adhesive is applied between the insulating substrate and two layer arrangements in the process of bonding them together. The adhesive may be selected from Ultra Violet (UV) curable adhesive material or thermally curable adhesive material, depending on the specific bonding process adopted. When UV curable adhesive material is selected, the insulating substrate would be limited to transparent material because UV light can only pass through transparent substrate to activate UV curable adhesive material. When thermally curable adhesive material is selected, there is no limitation for the insulating substrate. In one embodiment, epoxy based material which is thermally curable, e.g., prepreg, is used as adhesive.

However, adhesive need not be applied when it is unnecessary to carry out any bonding of the layer arrangement onto the insulating substrate. For example, when the insulating substrate is selected to be rubber-like material which may be stretched under a certain force, the insulating substrate can be attached to the first and the second layer arrangement under the application of force under a certain temperature and pressure.

After attaching the two layer arrangements and the insulating substrate, a grinding process may be applied to the first and the second layer arrangements. The two supply substrates of the two layer arrangements are ground to reduce their thickness, wherein the grinding may be conducted on the two supply substrates simultaneously or separately. The grinding may be stopped when a certain thickness is left for the two supply substrates such that the dielectric layers carrying or not carrying an integrated circuit are prevented from damage. For example, the remained thickness of the two supply substrates after grinding is kept in the range of 10 μm˜200 μm.

In another embodiment, the two layer arrangements may be pre-ground to a reduced thickness before they are attached to the Insulating substrate. Preferably, the thickness is in the range of 150 μm to 400 μm. In a further embodiment, the grinding is performed to completely remove the supply substrate without remaining a certain thickness.

Whether grinding is performed before or after attaching the two layer arrangements with the insulating substrate, an etching process may be applied to completely remove the supply substrates in the case that a certain thickness is remained. In a further embodiment, grinding is not performed, and the supply substrates are removed solely by etching.

The etching process may be selected from the current technology, i.e. wet etching and dry etching. Some examples of the etching method include liquid etching, plasma etching and reactive ion etching. In one embodiment, liquid etching is performed on the remained supply substrates wherein KOH or TMAH are used as the etching solution.

In a preferred embodiment, an etching-stop layer is provided in the layer arrangement defined above. When producing said layer arrangement, an etching-stop layer is directly formed on a supply substrate, followed by a dielectric layer formed on the etching-stop layer. The etching-stop layer comprises a stack or combined stacks of materials with etching-stop effect. Some examples of such materials include SiGe, silicon nitride (Si₃N₄), silicon oxide (SiO₂), silicon carbide and organic polymer material. The selection of the etching-stop material depends on the supply substrate material. In one embodiment, the etching-stop layer is selected from combined stacks of SiO₂ and Si₃N₄, which is formed on a silicon substrate.

Depending on the material selected to constitute the etching-stop layer, different process may be selected to forming such an etching-stop layer on a supply substrate. For example, a SiO₂ layer may be produced by thermal oxidation or chemical vapor deposition (CVD). A Si₃N₄ layer may also be produced by chemical vapor deposition (CVD), including low pressure chemical vapor deposition (LPCVD), atmospheric pressure chemical vapor deposition (APCVD) and plasma enhanced chemical vapor deposition (PECVD).

With an etching-stop layer positioned between the dielectric layer and the supply substrate of the layer arrangement, the etching process will etch away the supply substrate until arriving at the etching-stop layer, thereby protecting the dielectric layer which may be embedded with integrated circuit component.

The integrated circuit embedded in the dielectric layer is thus transferred to an insulating substrate. Such a device as a whole may be used as a packaging substrate wherein a series of post-processing is performed. Examples of post-processing include forming pads, solder ball, through vias, buried vias and blind vias, depending on the practical usage of the final integrated circuit.

The invention is further directed to a multi-layered integrated circuit device. The device comprises an insulating substrate on which surface a first dielectric layer is attached. A second dielectric layer is attached to an opposing surface of the insulating substrate. One or more integrated circuit components and related circuits are pre-fabricated onto at least one of the first and the second dielectric layers. The arrangement of the dielectric layers is such that the first dielectric layer is aligned with the second dielectric layer, so that the first and the second dielectric layers overlap substantially across the insulating substrate, thereby sandwiching the insulating substrate. The first dielectric layer can totally or partially overlap on the second dielectric layer.

In general, warping of the insulating substrate is due to an imbalance of interfacial stress on opposing surfaces of the insulating substrate caused by unequal contraction of the dielectric layers when the fabricated device is cooled from high temperatures in the course of fabrication. In order to minimise such warping, the coefficient of thermal expansion of the first dielectric layer is preferably at least substantially identical to the coefficient of thermal expansion of the second dielectric layer. The reason for so doing is to enable the two surfaces of the insulating substrate to be subject to the same interfacial stress that is exerted by the dielectric layers on both sides of the insulating substrate contract to the same extent when cooled, thereby achieving stress balance between the two opposing surfaces of the insulating. In a specific embodiment, the stress balance is achieved by attaching on both sides of the insulating substrate identically thick first and second dielectric layers having also the same thermal expansion coefficient.

The material comprised in each of the first and the second the dielectric layers can be any substance that is a poor conductor of electricity, but can at the same time support electrostatic fields while dissipating minimal energy in the form of heat. Typically, most dielectric materials are solids and include materials such as porcelain (ceramic), mica, glass, plastics, and the oxides of various metals. Dielectric materials can also be selected from standard liquid epoxy, polyimide, Teflon, cyanate resins or powdered resin materials, etc. One preferred example of a dielectric material which can be used presently is silicon dioxide (SiO₂). SiO₂ provides adequately high-capacitance gate insulation at the front end of a line and sufficiently low-k, crosstalk-free insulation between interconnect wiring levels at the back end. However, with more densely populated chip real estate and the introduction of low-resistance interconnect materials like copper, SiO₂ “fencing” may not be adequate. Thus, other materials with lower dielectric constants for interconnect applications and higher dielectric constants for gate or capacitor applications will be required. With smaller integrated circuit components, even lower or higher k materials may be needed.

In one embodiment, the device further comprises a first supply substrate and a second supply substrate. The first supply substrate is attached to the first dielectric layer to form a first layer arrangement, and the second substrate is attached to the second dielectric layer to form a second layer arrangement. The supply substrate is typically present as a temporal artefact from the fabrication of the dielectric layer and the integrated circuit components. The supply substrate serves as a platform on which the dielectric layer (and circuit components therein) may be fabricated so that they can be transferred with ease onto the insulating substrate. Once the dielectric layer has been transferred onto the insulating substrate, the supply substrate can be removed.

One or both of the first and the second supply substrate preferably comprises any material that can be easily removed by grinding or etching. For example, metals such as gold or semi-conductors such as silicon can be used to fabricate the supply substrate. In a preferred embodiment, the supply substrate is selected from elemental silicon, poly silicon, gold, aluminium, nickel or a combination thereof.

The insulating substrate can comprise any electrically non-conducting material, such as plastics, glass, ceramics, rubber and organic material (e.g. FR- and RO-series). In one embodiment, the insulating substrate comprises a flame retarding material. A popular choice for such a material is the flame retardant FR-4. FR-4 laminates are commonly used as base material for printed circuit boards. The term “FR” means Flame Retardant (to UL94V-0), and Type “4” indicates woven glass reinforced epoxy resin.

In a preferred embodiment, the device may further comprise one or more etching-stop layers for terminating the etching action of an etchant in the case where a chemical etchant is used to remove the supply layer. The etching-stop layer is positioned between the supply substrate and the dielectric layer of one or both of the two layer arrangements. The etching-stop layer may be selected from materials such as SiGe, silicon nitride (Si₃N₄), silicon oxide (SiO₂), silicon carbide and organic polymer material, etc. In another preferred embodiment, combined stacks of SiO₂ and Si₃N₄ are used to form the etching-stop layer.

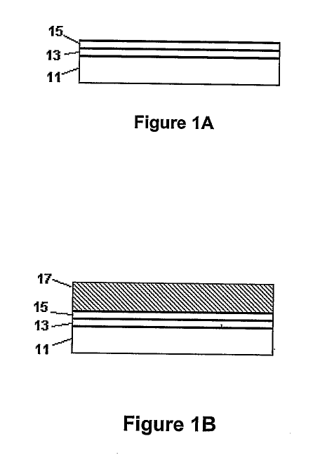

In FIG. 1, an example of an integrated passive circuit is given. The integrated passive circuit is fabricated using CMOS technology. In the first step as shown in FIG. 1A, etching stop layers 13, 15 are formed on a semiconductor substrate 11, preferably silicon wafer. In this embodiment, one etching stop layer 13 is SiO₂, the other layer 15 is Si₃N₄. The etching stop layers can be formed using method of thermal oxidation, LPCVD or PECVD. In the second step of FIG. 1B, one or more dielectric layer 17, with passive circuit embedded therein, is produced to cover the etching stop layers 13 and 15 using standard silicon wafer process. After this step, a layer arrangement wherein a silicon substrate carrying an integrated passive circuit is ready.

In one embodiment of this invention, the layer arrangement as shown in FIG. 1B is pre-fabricated using any existing technology, and the subsequent processing is directly applied on this layer arrangement. In another embodiment, this invention may also include the steps of fabricating an integrated passive circuit on a silicon substrate in the whole process of fabricating an integrated passive circuit on an insulating substrate.

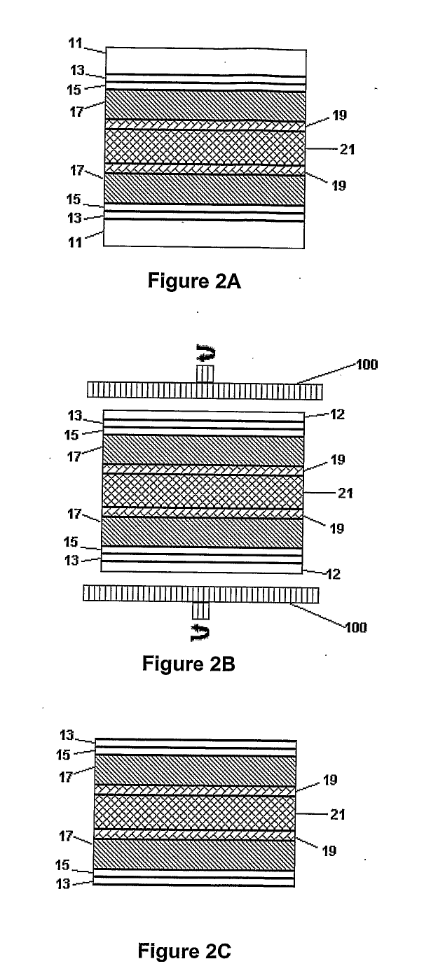

According to FIG. 2, a preferred process of transferring an integrated passive circuit from a silicon substrate 11 to an insulating substrate FR-4 21 is illustrated. Two layer arrangements are provided with the same structures as explained in FIG. 1B, except that one of the dielectric layer 17 of the two layer arrangements may be produced with or without metal pattern inside. In the latter case, there is no passive circuit embedded in this dielectric layer 17. Nevertheless, at least one of the two layer arrangements must contain an integrated passive circuit.

In FIG. 2A, the two layer arrangements are attached to an insulating substrate FR-4 21 via adhesive film prepreg 19. The two dielectric layers 17 are arranged to face the two opposing surface of the insulating substrate 21 respectively such that the insulating substrate 21 is sandwiched between the two layer arrangements. The attaching process is carried out using bonding or lamination procedure of PCB packaging under a certain temperature and pressure.

After bonding the two layer arrangements with the insulating substrate 21, the silicon substrates 11 are grinded until a thickness of 10 μm˜200 μm is left on each resultant silicon substrate 12. The reason of not grinding away all the silicon substrates is to prevent possible damage of embedded passive circuit in the dielectric layer 19. In this embodiment in FIG. 2B, two grinding machines 100 are utilized to grind the two silicon substrates 11 simultaneously. In another embodiment, one grinding machine 100 is used to grind the two silicon substrates 11 one by one.

The rest of the silicon substrates 12 are then etched away by liquid etching process with KOH and TMAH selected as the etching solution. The etching process stops at the etching stop layers 13 and 15, due to their insensitivity to etching solution. In another embodiment, etching process can be directly carried out without grinding process. As a result, the integrated passive circuit embedded in the dielectric layer 19 is successfully transferred to an insulating substrate 21 as shown in FIG. 2C.

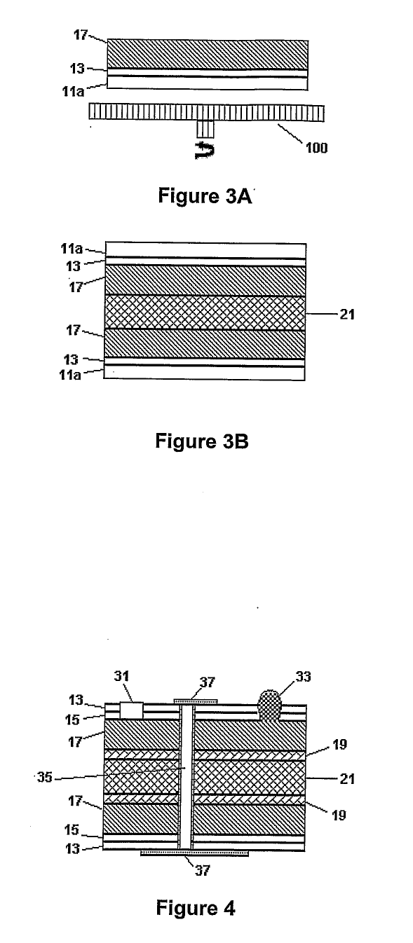

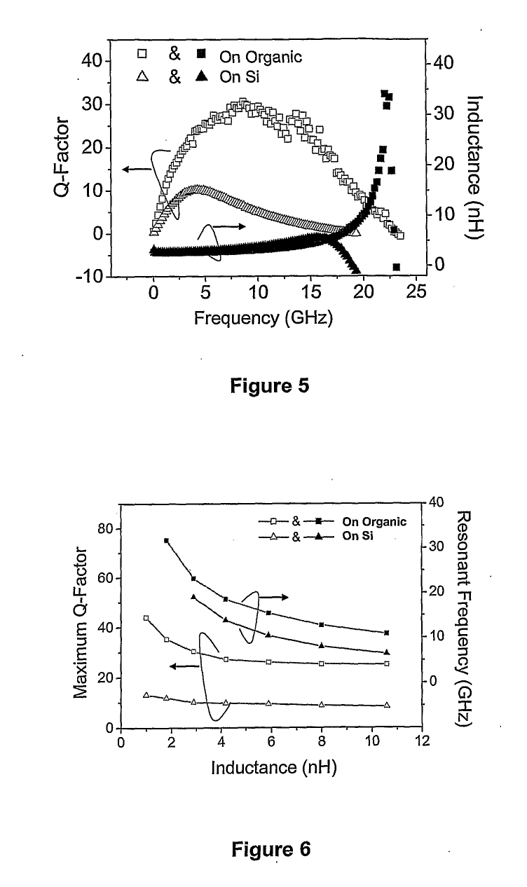

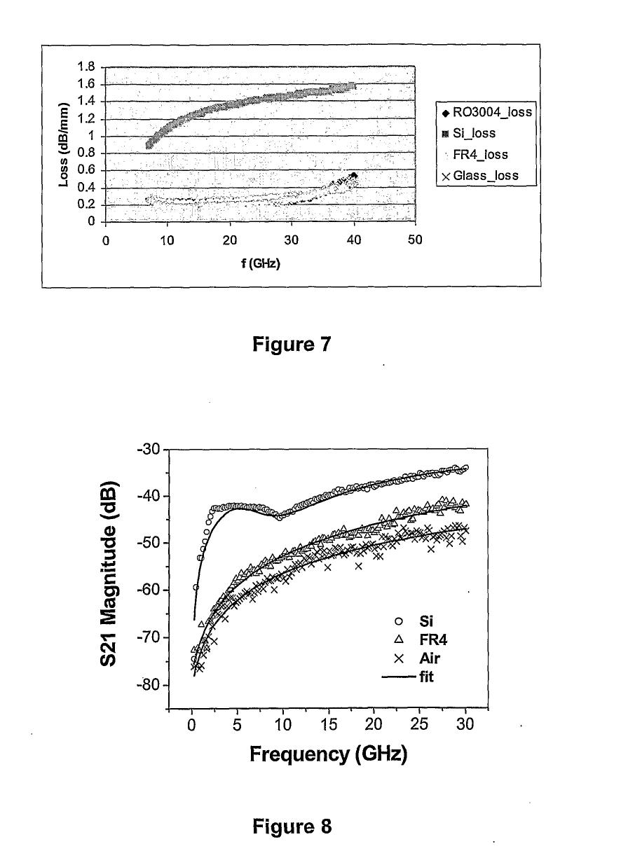

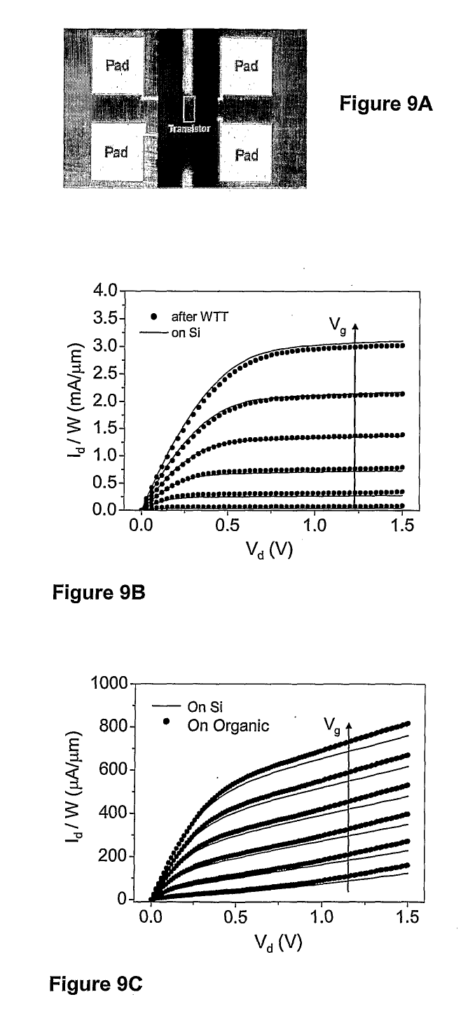

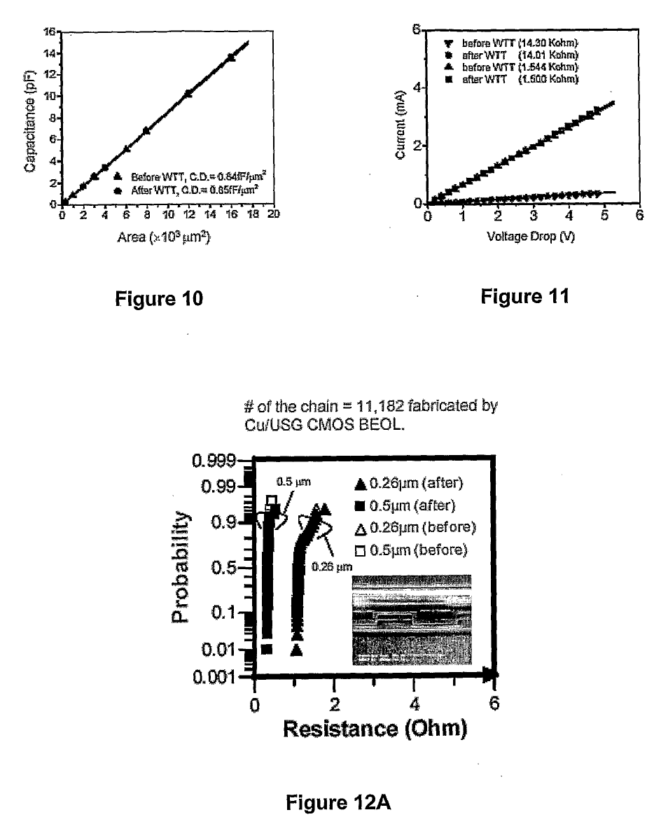

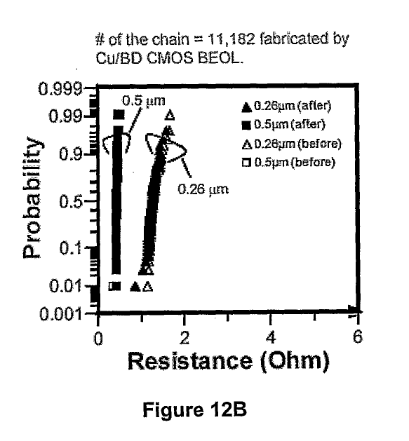

In a second embodiment, pre-grinding is performed before bonding the two layer arrangements with the insulating substrate 21. As shown in FIG. 3A, the layer arrangement is pre-ground using a grinding machine 100 with a certain thickness left. Preferably, the thickness of the left silicon substrate 11a is 150 μm˜400 μm. The two layer arrangements after pre-grinding are then attached to sandwich an insulating substrate 21 as explained in FIG. 2A. In the first embodiment, an adhesive film 19 is inserted between the insulating substrate 21 and two layer arrangements. In the second embodiment of FIG. 3B, the insulating substrate 21 can be directly bonded with the two layer arrangements under certain temperature and pressure, if the insulating substrate is made of rubber-like material which may be stretched under a certain force.

In the next step, the bonded structure can either undergo a combined grinding and etching process, or a single etching process, similar to the first embodiment explained above.

After the integrated passive circuit is attached on the insulating substrate 21, the whole device may be used as a packaging substrate. FIG. 4 lists some post-processing which may be performed on this final device, such as opening pads 31, forming solder ball 33, and producing through via 35 with metal 37 connected at both ends.

Although the present invention has been disclosed and illustrated with respect to preferred embodiments thereof, it is to be understood that the invention is not to be so limited and that other changes and modifications can be made within the full intended scope of the invention as hereinafter claimed.

1. A method of forming an integrated circuit component on an insulating substrate, comprising:
providing a first layer arrangement and a second layer arrangement, each layer arrangement comprising a supply substrate and a dielectric layer, the dielectric layer of at least one of said layer arrangements comprising the integrated circuit component therein;
attaching the first layer arrangement on one surface of the insulating substrate with the dielectric layer of the first layer arrangement facing the insulating substrate, and
attaching the second layer arrangement on an opposing surface of the insulating substrate with the dielectric layer of the second layer arrangement facing the insulating substrate,
wherein
the first layer arrangement and the second layer arrangement are so arranged to sandwich at least a portion of the insulating substrate between the first and the second layer arrangements.

2. The method of claim 1, wherein the properties of at least one of the first layer arrangement and the second layer arrangement are selected such that interfacial stress between the first layer arrangement and the insulating substrate is compensated by the interfacial stress between the second layer arrangement and the insulating substrate.

3. The method of claim 1, wherein the first layer arrangement and the second layer arrangement are so arranged to sandwich the insulating substrate entirely between the first layer arrangement and the second layer arrangement.

4. The method of claim 1, wherein the thickness of the first layer arrangement is selected to be at least substantially identical to the thickness of the second layer arrangement.

5. The method of claim 4, wherein the thickness of the supply substrate in the first layer arrangement is selected to be at least substantially identical to the supply substrate of the second layer arrangement.

6. The method of claim 1, wherein the dielectric layer of the second layer arrangement is selected to be at least substantially identical in structure to the dielectric layer of the first layer arrangement.

7. The method of claim 1, wherein the value of the overall coefficient of thermal expansion of the first layer arrangement is selected to be at least substantially identical to the value of the overall coefficient of thermal expansion of the second layer arrangement.

8. The method of claim 7, wherein the value of the coefficient of thermal expansion of the supply substrate of the first layer arrangement is selected to be at least substantially identical to the value of the coefficient of thermal expansion of the supply substrate of the second layer arrangement.

9. The method of claim 1, wherein the first layer arrangement and the second layer arrangement are attached to the insulating substrate at substantially the same ambient temperature and/or the same time.

10. The method of claim 1, further comprising applying an adhesive between the insulating substrate and the dielectric layer of at least one of the first and the second layer arrangement.

11. The method of claim 10, wherein the adhesive is selected from a group consisting of Ultra Violet (UV) curable adhesive material and thermally curable adhesive material.

12. The method of claim 1, further comprising
grinding the first and the second layer arrangements to reduce the thickness of the supply substrate before attaching said layer arrangements to the insulating substrate.

13. The method of claim 1, further comprising
grinding the first and the second layer arrangements to reduce the thickness of the supply substrate after attaching said layer arrangements to the insulating substrate.

14. The method of claim 12, further comprising etching the supply substrate of the first and the second layer arrangements after attachment thereof to the insulating substrate.

15. The method of claim 1, wherein
the supply substrate is selected from a group consisting of elemental silicon, poly-silicon, gold, aluminium, nickel and a combination thereof.

16. The method of claim 1, wherein
the insulating substrate is selected from a group consisting of ceramics, glass, rubber, organic material (e.g. FR- and RO-series) and a combination thereof.

17. The method of claim 1, wherein providing said first and said second layer arrangement comprises
forming an etching-stop layer on said supply substrate, and
forming said dielectric layer on the etching-stop layer.

18. The method of claim 17, wherein
the etching-stop layer is selected from a group consisting of SiO₂, Si₃N₄ and a combination thereof.

19. The method of claim 17, wherein
the etching-stop layer is formed on a supply substrate by a process selected from thermal oxidation, low pressure chemical vapor deposition (LPCVD) and plasma enhanced chemical vapor deposition (PECVD).

20. The method of claim 1, further comprising
forming at least one integrated circuit component in the dielectric layer of at least one of said first and second layer arrangements.

21. The method of claim 20, wherein the at least one integrated circuit component is formed in the dielectric layer by a process selected from thin film technology, thick film technology, and sol-gel technology.

22. The method of claim 20, wherein the integrated circuit component is selected from transistors, amplifiers, transmitters, LEDs, inductors, capacitors, resistors, RF filters, I/O pads, metal wires, antennas and their synthetic function blocks.

23. A device carrying an integrated circuit component, comprising
a first dielectric layer attached to a surface of an insulating substrate, and a second dielectric layer attached to an opposing surface of the insulating substrate,
at least one of said first and said second dielectric layer comprising the integrated circuit component therein,
wherein
the first dielectric layer and the second dielectric layer are so arranged to sandwich at least a portion of the insulating substrate between the first and the second dielectric layers.

24. The device of claim 23, wherein the value of the overall coefficient of thermal expansion of the first dielectric layer is at least substantially identical to the value of the overall coefficient of thermal expansion of the second dielectric layer.

25. The device of claim 23, wherein the structure of the first dielectric layer and the structure of the second dielectric layer are at least substantially identical.

26. The device of claim 23, wherein said insulating substrate comprises a material selected from the group consisting of ceramics, glass, rubber and organic material (e.g. FR- and RO-series).

27. The device of claim 23, wherein at least one of said first and said second layer arrangements further comprises an etching-stop layer positioned adjacently to the dielectric layer.

28. The device of claim 23, further comprising
a first supply substrate attached to the first dielectric layer, thereby forming a first layer arrangement, and
a second supply substrate attached to the second dielectric layer, thereby forming a second layer arrangement.

29. The device of claim 28, wherein the thickness of the first supply substrate and the thickness of the second supply substrate are at least substantially identical.

30. The device of claim 29, wherein the supply substrate is selected from the group consisting of elemental silicon, poly-silicon, gold, aluminium, nickel and a combination thereof.

31. The device of claim 28, wherein at least one of said first and said second layer arrangements further comprise an etching-stop layer positioned between the supply substrate and the dielectric layer.

32. The device of claim 31, wherein the etching-stop layer comprises a material selected from SiO₂, Si₃N₄, and a combination thereof.

33. A device carrying an integrated circuit component, comprising
a first layer arrangement comprising a supply substrate and a dielectric layer attached to a surface of an insulating substrate with the dielectric layer of the first layer arrangement facing the insulating substrate,
a second layer arrangement comprising a supply substrate and a dielectric layer attached to an opposing surface of the insulating substrate with the dielectric layer of the second layer arrangement facing the insulating substrate,
the dielectric layer of at least one of the layer arrangements comprising the integrated circuit component therein;
wherein
the first layer arrangement and the second layer arrangement are so arranged to sandwich at least a portion of the insulating substrate between the first and the second layer arrangements.

34. The method of claim 13, further comprising
etching the supply substrate of the first and the second layer arrangements after attachment thereof to the insulating substrate.
